(19) United States
(12) Patent Application Publication
(10) Pub. No.: US 2025/0159843 A1
(43) Pub. Date: May 15, 2025

(54) COOLING SYSTEM ASSEMBLY

(71) Applicant: Cooler Master Co., Ltd., Taipei City (TW)

(72) Inventors: Tung-Yang Shieh, Taipei City (TW); Chia-Chin Chan, Taipei City (TW); Keng-Yu Lin, Taipei City (TW)

(21) Appl. No.: 18/945,717

(22) Filed: Nov. 13, 2024

(30) Foreign Application Priority Data
Nov. 14, 2023 (TW) 112212312

(51) Int. Cl. H05K 7/20

(52) U.S. Cl. CPC H05K 7/2039; H05K 7/20327; H05K 7/20336

(57) ABSTRACT

A cooling system assembly may include a heatsink unit and a water block unit. The heatsink unit is configured to enable a first cooling liquid to undergo a phase-change. The heatsink unit includes a heat pipe heatsink comprising a first thermal transfer surface and a second thermal transfer surface. The second thermal transfer surface is opposite the first thermal transfer surface. The first thermal transfer surface is configured to enable a heat to be transported from at least one packaged integrated circuit to the heat pipe heatsink. The water block unit is configured to enable a second cooling liquid to flow through the water block unit. The water block unit is thermally coupled to the second thermal transfer surface. The second thermal transfer surface is configured to enable the heat to be further transported from the heat pipe heatsink to the water block unit.

### RELATED APPLICATIONS

This US application claims the benefit of priority to Taiwan application no. 112212312, filed on Nov. 14, 2023, of which is incorporated herein by reference in its entirety.

### TECHNICAL FIELD

The present disclosure relates to heat-transfer components and assemblies, and more particularly, but not limited to, heatsink unit assemblies.

### BACKGROUND OF THE INVENTION

With increasing processing speed and performance of electronic devices, the amount of heat generated during operation of an electronic device has increased. The heat generation increases the temperature of the electronic device and, if the heat cannot be dissipated effectively, the reliability and performance of the electronic device is reduced. To prevent overheating of an electronic device, cooling systems such as air-cooling systems and liquid cooling systems are used to efficiently dissipate the heat generated by the electronic device and, thereby ensure the standard operation of the electronic device.

In the case of air-cooling systems for packaged integrated circuits, heat is dissipated from an upper surface of a packaged integrated circuit via upper surface adherence of a heatsink or water block unit to the packaged integrated circuit. The heatsink or water block unit is commonly mounted to the packaged integrated circuits via attachment members such as screws and push pins. Given same design parameters however, increasing thermal conductivity of air-cooling systems continue to be challenging.

### SUMMARY OF THE INVENTION

The present disclosure provides a cooling system assembly with higher thermal conductivity.

In some embodiments cooling system assembly, including a heatsink unit and a water block unit. The heatsink unit is configured to enable a first cooling liquid to undergo a phase-change. The heatsink unit includes a heat pipe heatsink. The heat pipe heatsink includes a first thermal transfer surface and a second thermal transfer surface. The second thermal transfer surface is opposite the first thermal transfer surface. The first thermal transfer surface is configured to enable a heat to be transported from at least one packaged integrated circuit to the heat pipe heatsink. The water block unit is configured to enable a second cooling liquid to flow through the water block unit. The water block unit is thermally coupled to the second thermal transfer surface. The second thermal transfer surface is configured to enable the heat to be further transported from the heat pipe heatsink to the water block unit.

In some embodiments cooling system assembly, wherein the heatsink unit further includes a fin stack and a plurality of heat pipes. Each plurality of heat pipes is thermally coupled to the heat pipe heatsink on a heatsink end and each plurality of heat pipes is thermally coupled to the fin stack on a fin end opposite the heatsink end.

In some embodiments cooling system assembly, wherein the fin stack is disposed on one side of the heat pipe heatsink and the plurality of heat pipes includes seven plurality of heat pipes. Four of the seven plurality of heat pipes are parallel aligned at a bottom distance of the fin stack from a bottom of the fin stack. Three of the seven plurality of heat pipes are parallel aligned at an upper distance of the fin stack from the bottom of the fin stack. The upper distance is larger than the bottom distance. In some embodiments cooling system assembly, wherein the heat pipe heatsink further includes a heatsink length, and the fin stack includes a fin length and a fin width. The fin length is greater than the fin width and the heatsink length.

In some embodiments cooling system assembly, wherein the water block unit includes a heat exchanger tubing and a heat dissipation cover. The heat exchanger tubing is thermally coupled between the second thermal transfer surface and the heat dissipation cover. The heat exchanger tubing includes an inlet tube connector and an outlet tube connector. The inlet tube connector is configured to enable the second cooling liquid to be transported into the water block unit. The outlet tube connector is configured to enable the second cooling liquid to be transported out of the water block unit. The heat exchanger tubing is configured to enable the heat to be further transported from the second thermal transfer surface to the second cooling liquid and then out of the water block unit. In some embodiments cooling system assembly, wherein the second thermal transfer surface includes a second surface groove, the heat dissipation cover includes a plate surface groove, and the heat exchanger tubing further includes a second surface side and a heat dissipation cover side. The second surface side is opposite the heat dissipation cover side and the second surface side abuts the second surface groove and the heat dissipation cover side abuts the plate surface groove. The inlet tube connector and the outlet tube connector are disposed on a same side of the water block unit. In some embodiments cooling system assembly, wherein the water block unit further includes a second fin stack, and the heat dissipation cover includes a third thermal transfer surface. The second fin stack is thermally coupled to the third thermal transfer surface. The second fin stack is configured to enable the heat to be further transported from the water block unit to the second fin stack. In some embodiments cooling system assembly, wherein the heat dissipation cover is a vapor chamber. The vapor chamber is configured to enable the phase-change of a third cooling liquid in the vapor chamber.

In some embodiments cooling system assembly, wherein the water block unit includes a base plate cavity and a plurality of heat transfer surface features. The plurality of heat transfer surface features is disposed in the base plate cavity. The base plate cavity is thermally coupled centrally on the second thermal transfer surface. The plurality of heat transfer surface features is configured to enable the heat to be further transported from the heat pipe heatsink to the plurality of heat transfer surface features, and then to the second cooling liquid, and then out of the water block unit.

In some embodiments cooling system assembly, wherein the water block unit further includes a cover plate, a plate inlet, and a plate outlet. The cover plate is coupled on the water block unit. The plurality of heat transfer surface features is between the second thermal transfer surface and the cover plate. The plate inlet and the plate outlet are respectively fluidly coupled through the cover plate to the base plate cavity. The plate inlet is configured to enable the second cooling liquid to be transported into the water block unit. The plate outlet is configured to enable the second cooling liquid to be transported out of the water block unit.

In some embodiments cooling system assembly, wherein the water block unit further includes a liquid cooling pumping unit. The liquid cooling pumping unit includes an inlet connector and an outlet connector. The liquid cooling pumping unit is coupled on the water block unit. The plurality of heat transfer surface features is between the second thermal transfer surface and the liquid cooling pumping unit. The liquid cooling pumping unit is fluidly communicated with the base plate cavity. The liquid cooling pumping unit is configured to enable a pressure and a flow of the second cooling liquid to be increased and transported through the plurality of heat transfer surface features and out of the water block unit.

In some embodiments cooling system assembly, wherein the water block unit includes a second plurality of heat pipes and a second fin stack, and the heat pipe heatsink further includes a plurality of second heat pipe grooves. Each second plurality of heat pipes is thermally coupled in each plurality of second heat pipe grooves. The second fin stack is thermally coupled to the heat pipe heatsink. The second plurality of heat pipes is between the second thermal transfer surface and the second fin stack. The second plurality of heat pipes is configured to enable the heat to be further transported from the second thermal transfer surface to the second cooling liquid and away from the heat pipe heatsink.

In some embodiments cooling system assembly, further including a plurality of fan devices. Each plurality of fan devices is disposed on the fin stack or on the fin stack and the second fin stack. Each plurality of fan devices is configured to enable air to be forced across the fin stack and the second fin stack.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of heatsink and water block units incorporating aspects of the presently disclosed principles are illustrated by way of example, and not by way of limitation.

FIG. 1A illustrates a perspective view of a cooling system assembly, in accordance with various embodiments of the present disclosure.

FIG. 1B illustrates another perspective view of the cooling system assembly of FIG. 1A, in accordance with various embodiments of the present disclosure.

FIG. 1C illustrates an exploded view of the cooling system assembly of FIG. 1A, in accordance with various embodiments of the present disclosure.

FIG. 1D illustrates another exploded view of the cooling system assembly of FIG. 1A, in accordance with various embodiments of the present disclosure.

FIG. 2A illustrates a perspective view of an alternative cooling system assembly, in accordance with various embodiments of the present disclosure.

FIG. 2B illustrates an exploded view of the alternative cooling system assembly of FIG. 2A, in accordance with various embodiments of the present disclosure.

FIG. 2C illustrates another exploded view of the alternative cooling system assembly of FIG. 2A, in accordance with various embodiments of the present disclosure.

FIG. 3A illustrates a perspective view of another alternative cooling system assembly, in accordance with various embodiments of the present disclosure.

FIG. 3B illustrates an exploded view of the another alternative cooling system assembly of FIG. 3A, in accordance with various embodiments of the present disclosure.

FIG. 3C illustrates another exploded view of the another alternative cooling system assembly of FIG. 3A, in accordance with various embodiments of the present disclosure.

FIG. 4A illustrates a perspective view of yet another alternative cooling system assembly, in accordance with various embodiments of the present disclosure.

FIG. 4B illustrates an exploded view of the yet another alternative cooling system assembly of FIG. 4A, in accordance with various embodiments of the present disclosure.

### DETAILED DESCRIPTION

The following describes various principles related to components and assemblies for electronic devices cooling by way of reference to specific examples of cooling system assemblies, including specific arrangements and examples of heatsink units and water block units embodying innovative concepts. More particularly, but not exclusively, such innovative principles are described in relation to selected examples of heat pipe heatsinks thermally coupled to water block units, and well-known functions or constructions are not described in detail for purposes of succinctness and clarity. Nonetheless, one or more of the disclosed principles can be incorporated in various other embodiments of heat pipe heatsinks thermally coupled to water block units to achieve any of a variety of desired outcomes, characteristics, and/or performance criteria.

Thus, heat pipe heatsinks thermally coupled to water block units having attributes that are different from those specific examples discussed herein can embody one or more of the innovative principles, and can be used in applications not described herein in detail. Accordingly, embodiments of heat pipe heatsinks thermally coupled to water block units not described herein in detail also fall within the scope of this disclosure, as will be appreciated by those of ordinary skill in the relevant art following a review of this disclosure.

Example embodiments as disclosed herein are directed to cooling system assemblies that can be used in cooling systems to dissipate high heat loads. The cooling system may be configured on a chassis, within a chassis, or as part of an electronics system that includes heat producing electronic components to be cooled. The cooling system includes at least one cooling system assembly. The cooling system assembly may be coupled to the chassis via a fastener (e.g., bolts, screws, etc.), transporting heat away from heat producing electronic components to be cooled and/or to an outside of the chassis or electronics system. The cooling system may further comprise one or more liquid-based cooling loops.

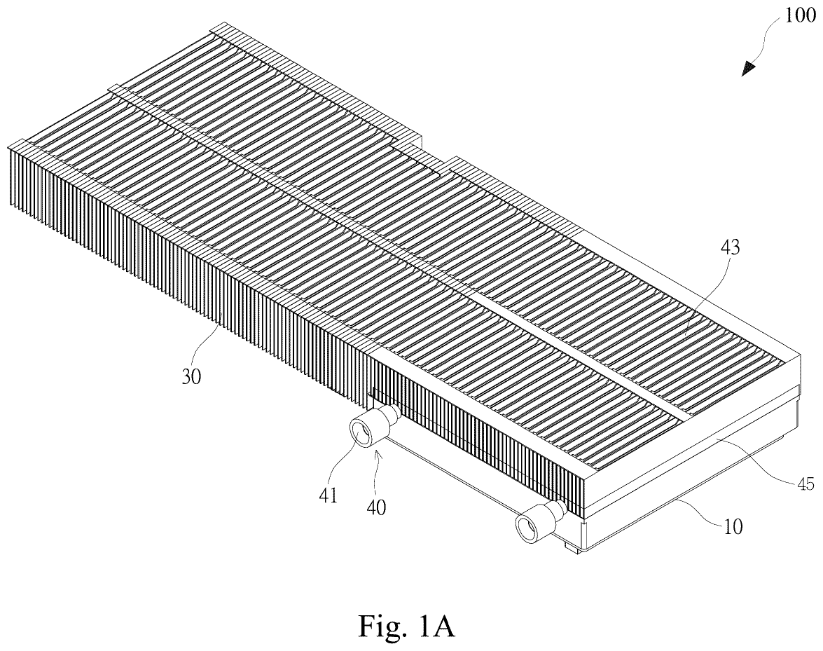

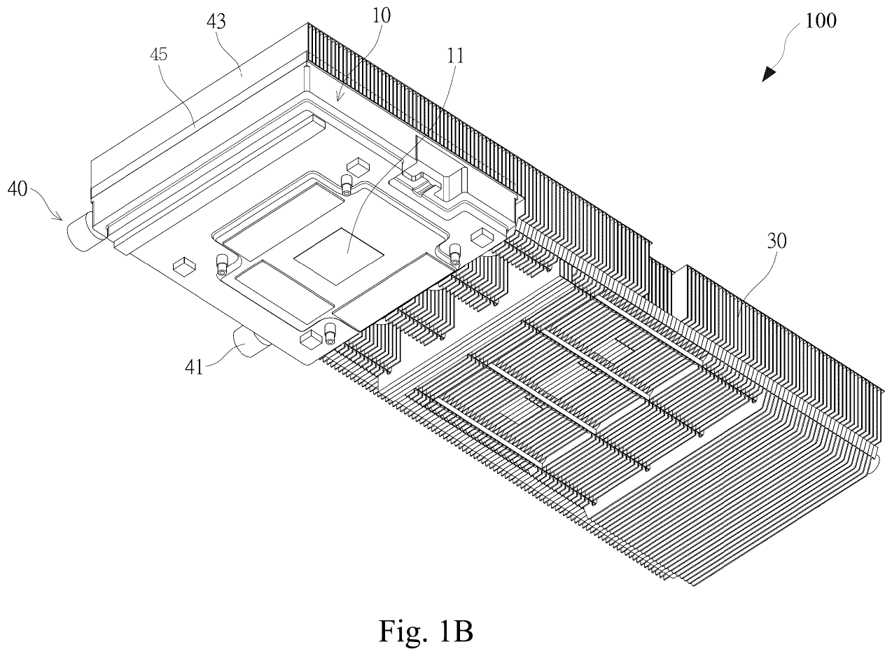

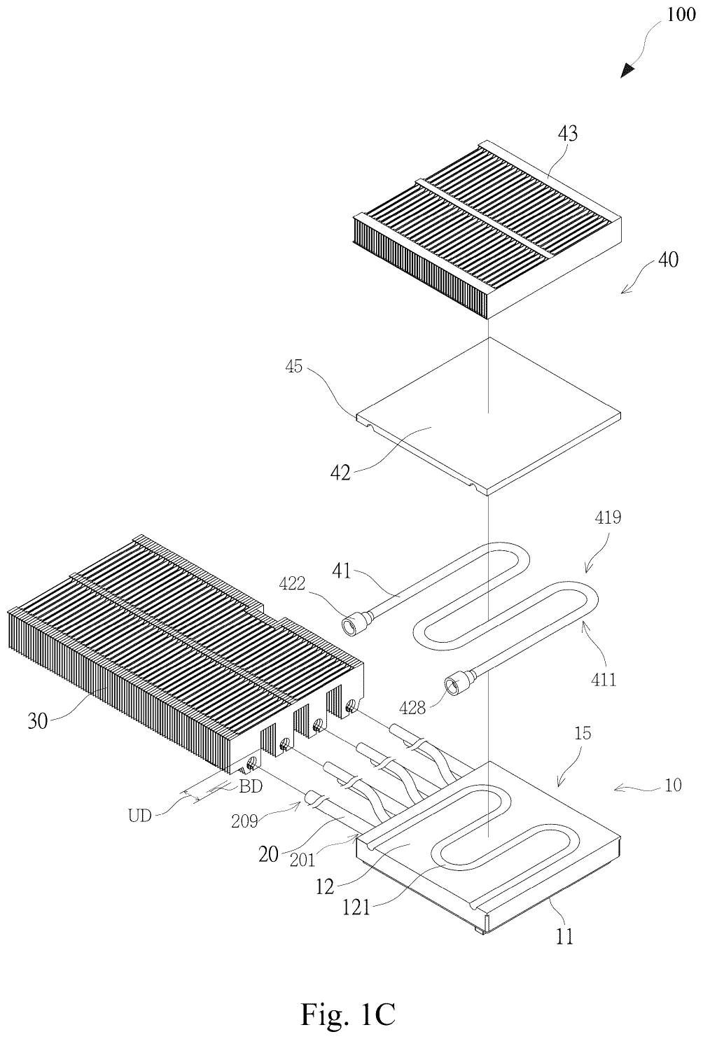

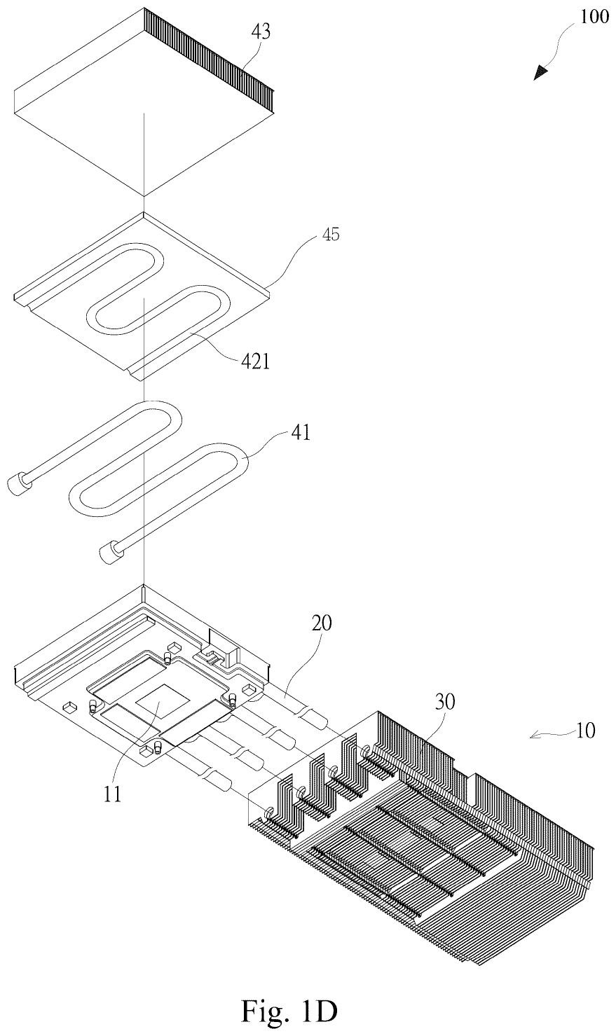

FIGS. 1A, 1B, 1C, and 1D illustrate a cooling system assembly 100, in accordance with various embodiments of the present disclosure. The cooling system assembly 100, includes a heatsink unit 10 and a water block unit 40. The heatsink unit 10 is configured to enable a first cooling liquid to undergo a phase-change. The heatsink unit 10 includes a heat pipe heatsink 15. The heat pipe heatsink 15 includes a first thermal transfer surface 11 and a second thermal transfer surface 12. The second thermal transfer surface 12 is opposite the first thermal transfer surface 11. The first thermal transfer surface 11 is configured to enable a heat to be transported from at least one packaged integrated circuit (not shown) to the heat pipe heatsink 15. The water block unit 40 is configured to enable a second cooling liquid to flow through the water block unit 40. The water block unit 40 is thermally coupled to the second thermal transfer surface 12. The second thermal transfer surface 12 is configured to enable the heat to be further transported from the heat pipe heatsink 15 to the water block unit 40.

In some embodiments, the heatsink unit 10 further includes a fin stack 30 and a plurality of heat pipes 20. Each plurality of heat pipes 20 is thermally coupled to the heat pipe heatsink 15 on a heatsink end 201 and each plurality of heat pipes 20 is thermally coupled to the fin stack 30 on a fin end 209 opposite the heatsink end 201.

In some embodiments, the fin stack 30 is disposed on one side of the heat pipe heatsink 15 and the plurality of heat pipes 20 includes seven plurality of heat pipes 20. Four of the seven plurality of heat pipes 20 are parallel aligned at a bottom distance BD of the fin stack 30 from a bottom of the fin stack 30. Three of the seven plurality of heat pipes 20 are parallel aligned at an upper distance UD of the fin stack 30 from the bottom of the fin stack 30. The upper distance UD is larger than the bottom distance BD. In some embodiments, the heat pipe heatsink 15 further includes a heatsink length HL, and the fin stack 30 includes a fin length FL and a fin width FW. The fin length FL is greater than the fin width FW and the heatsink length HL.

In some embodiments, the water block unit 40 includes a heat exchanger tubing 41 and a heat dissipation cover 45. The heat exchanger tubing 41 is thermally coupled between the second thermal transfer surface 12 and the heat dissipation cover 45. The heat exchanger tubing 41 includes an inlet tube connector 422 and an outlet tube connector 428. The inlet tube connector 422 is configured to enable the second cooling liquid to be transported into the water block unit 40. The outlet tube connector 428 is configured to enable the second cooling liquid to be transported out of the water block unit 40. The heat exchanger tubing 41 is configured to enable the heat to be further transported from the second thermal transfer surface 12 to the second cooling liquid and then out of the water block unit 40. In some embodiments, the second thermal transfer surface 12 includes a second surface groove 121, the heat dissipation cover 45 includes a plate surface groove 421, and the heat exchanger tubing 41 further includes a second surface side 411 and a heat dissipation cover side 419. The second surface side 411 is opposite the heat dissipation cover side 419 and the second surface side 411 abuts the second surface groove 121 and the heat dissipation cover side 419 abuts the plate surface groove 421. The inlet tube connector 422 and the outlet tube connector 428 are disposed on a same side of the water block unit 40. In some embodiments the heat exchanger tubing 41 can be embedded in the second thermal transfer surface (not shown), or the heat exchanger tubing 41 can be embedded in the heat dissipation cover (not shown). In some embodiments, the inlet tube connector 422 and an outlet tube connector 428 are coupled to openings of the second surface groove 121 and the plate surface groove 421 without the heat exchanger tubing 41. In some embodiments, the second surface groove 121 comprises a second channel (not shown) through the second thermal transfer surface 12 and the inlet tube connector 422 and an outlet tube connector 428 are coupled to openings of the second channel. In some embodiments, the plate surface groove 421 comprises a plate channel (not shown) through the heat dissipation cover 45 and the inlet tube connector 422 and an outlet tube connector 428 are coupled to openings of the plate channel. In some embodiments, the water block unit 10 further includes a second fin stack 43, and the heat dissipation cover 45 includes a third thermal transfer surface 42. The second fin stack 43 is thermally coupled to the third thermal transfer surface 42. The second fin stack 43 is configured to enable the heat to be further transported from the water block unit 10 to the second fin stack 43. In some embodiments, the heat dissipation cover 45 is a vapor chamber. The vapor chamber is configured to enable the phase-change of a third cooling liquid in the vapor chamber.

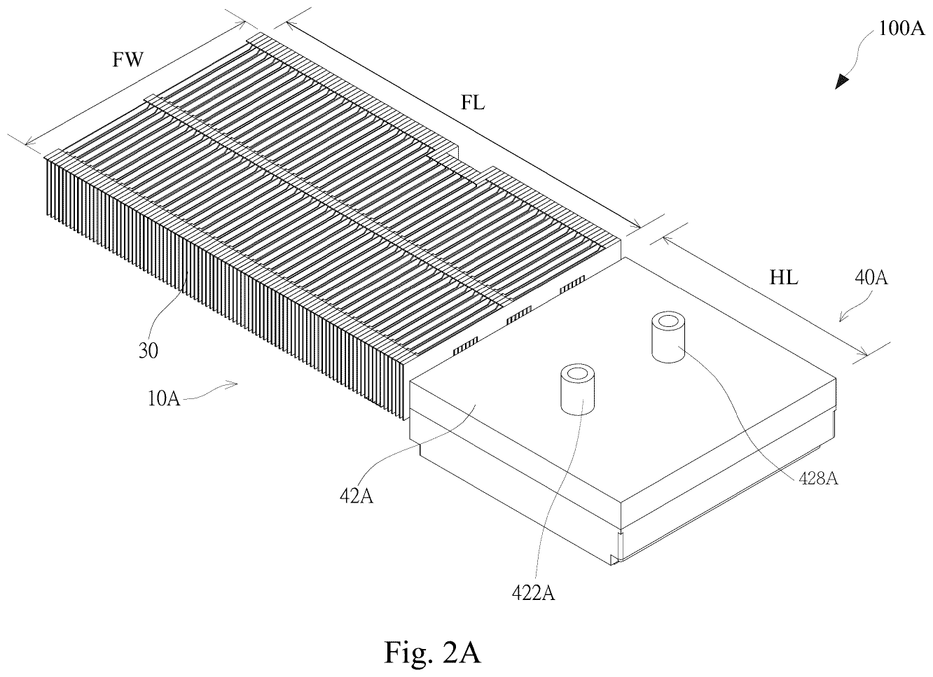

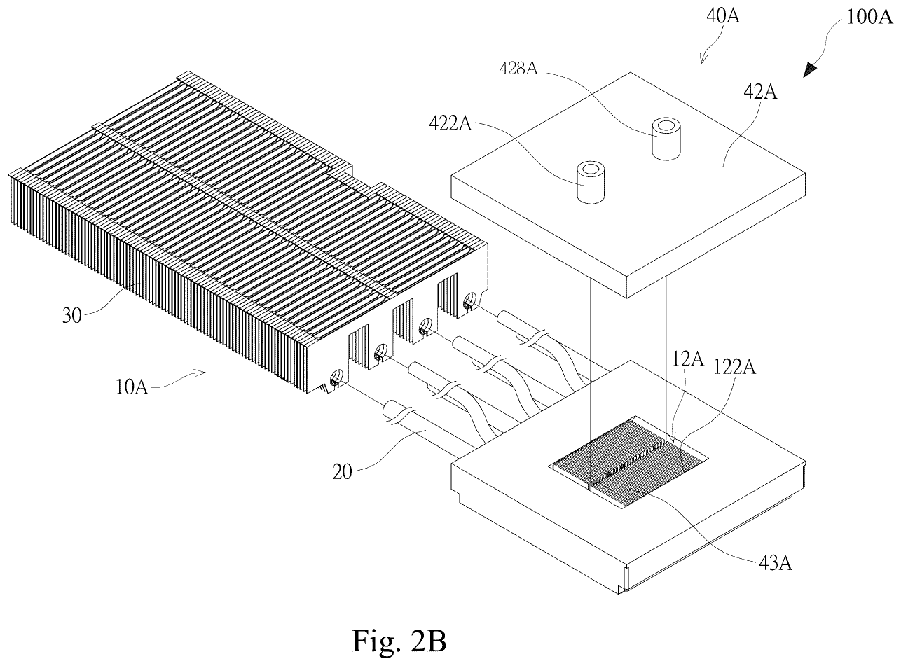

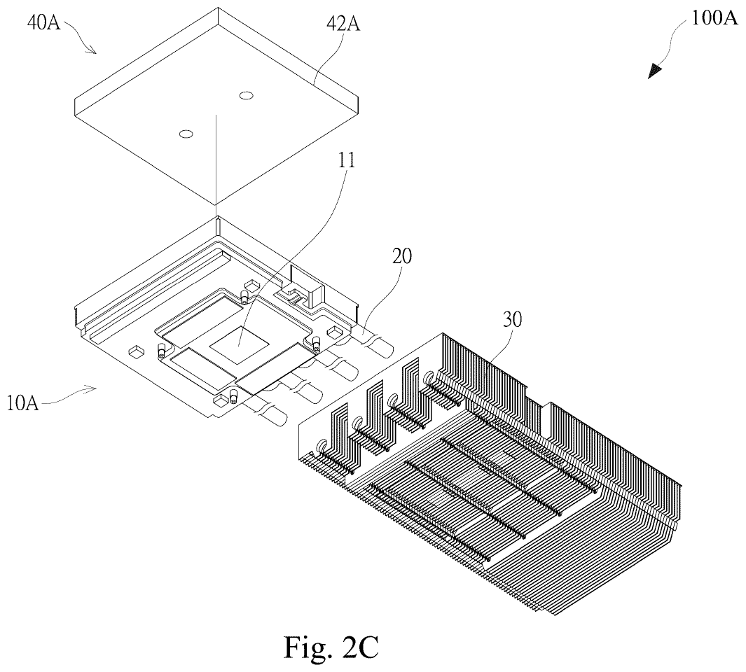

FIGS. 2A, 2B, and 2C illustrate an alternative cooling system assembly 100A, in accordance with various embodiments of the present disclosure. The alternative cooling system assembly 100A may be similar in some respects to the cooling system assembly 100 of FIGS. 1A, 1B, 1C, and 1D, and therefore may be best understood with reference thereto where like numerals designate like components not described again in detail. The water block unit 40A of the alternative cooling system assembly 100A includes a base plate cavity 122A and a plurality of heat transfer surface features 43A. The plurality of heat transfer surface features 43A is disposed in the base plate cavity 122A. The base plate cavity 122A is thermally coupled centrally on the second thermal transfer surface 12A. The plurality of heat transfer surface features 43A is configured to enable the heat to be further transported from the heat pipe heatsink 15 to the plurality of heat transfer surface features 43A, and then to the second cooling liquid, and then out of the water block unit 40A.

In some embodiments, the water block unit 40A further includes a cover plate 42A, a plate inlet 422A, and a plate outlet 428A. The cover plate 42A is coupled on the water block unit 40A. The plurality of heat transfer surface features 43A is between the second thermal transfer surface 12A and the cover plate 42A. The plate inlet 422A and the plate outlet 428A are respectively fluidly coupled through the cover plate 42A to the base plate cavity 122A. The plate inlet 422A is configured to enable the second cooling liquid to be transported into the water block unit 40A. The plate outlet 428A is configured to enable the second cooling liquid to be transported out of the water block unit 40A.

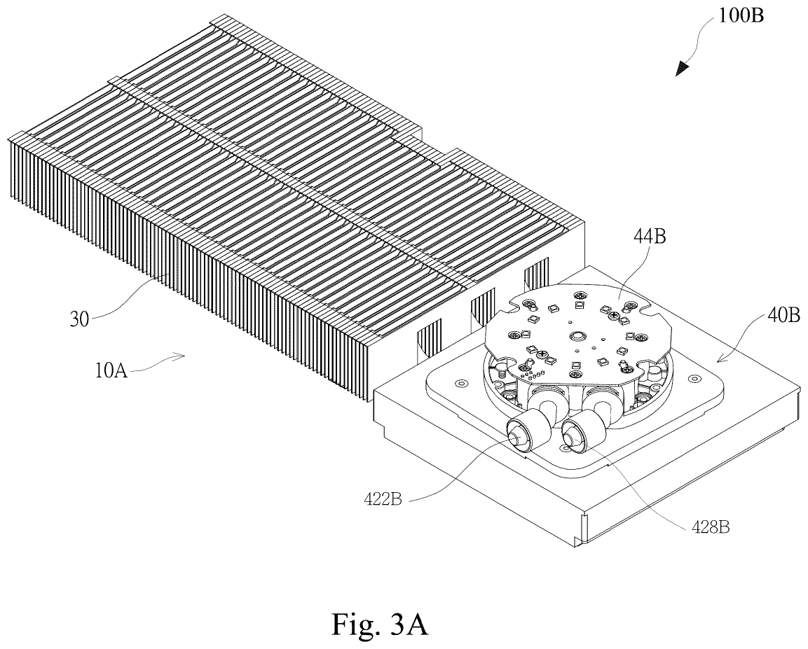

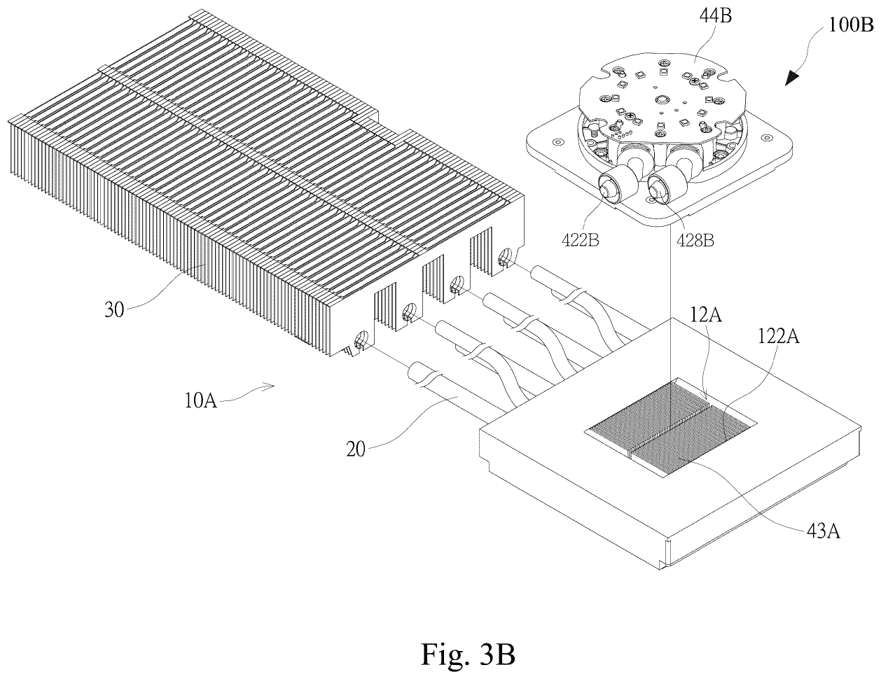

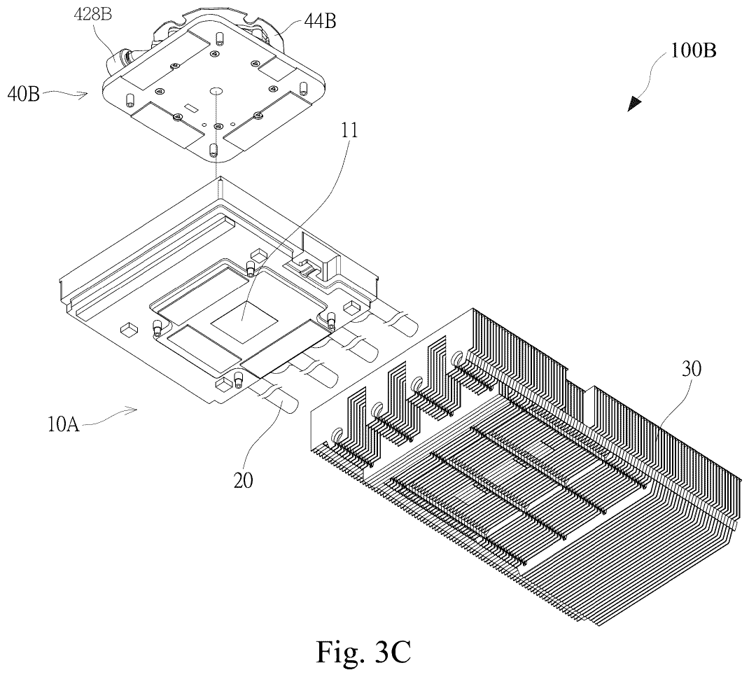

FIGS. 3A, 3B, and 3C illustrate another alternative cooling system assembly 100B, in accordance with various embodiments of the present disclosure. The another alternative cooling system assembly 100B may be similar in some respects to the cooling system assembly 100 of FIGS. 1A, 1B, 1C, and 1D, and the alternative cooling system assembly 100A of FIGS. 2A, 2B, and 2C, and therefore may be best understood with reference thereto where like numerals designate like components not described again in detail. The water block unit 40B of the another alternative cooling system assembly 100B further includes a liquid cooling pumping unit 44B. The liquid cooling pumping unit 44B includes an inlet connector 422B and an outlet connector 428B. The liquid cooling pumping unit 44B is coupled on the water block unit 40B. The plurality of heat transfer surface features 43A is between the second thermal transfer surface 12A and the liquid cooling pumping unit 44B. The liquid cooling pumping unit 44B is fluidly communicated with the base plate cavity 122A. The liquid cooling pumping unit 44B is configured to enable a pressure and a flow of the second cooling liquid to be increased and transported through the plurality of heat transfer surface features 43A and out of the water block unit 40B.

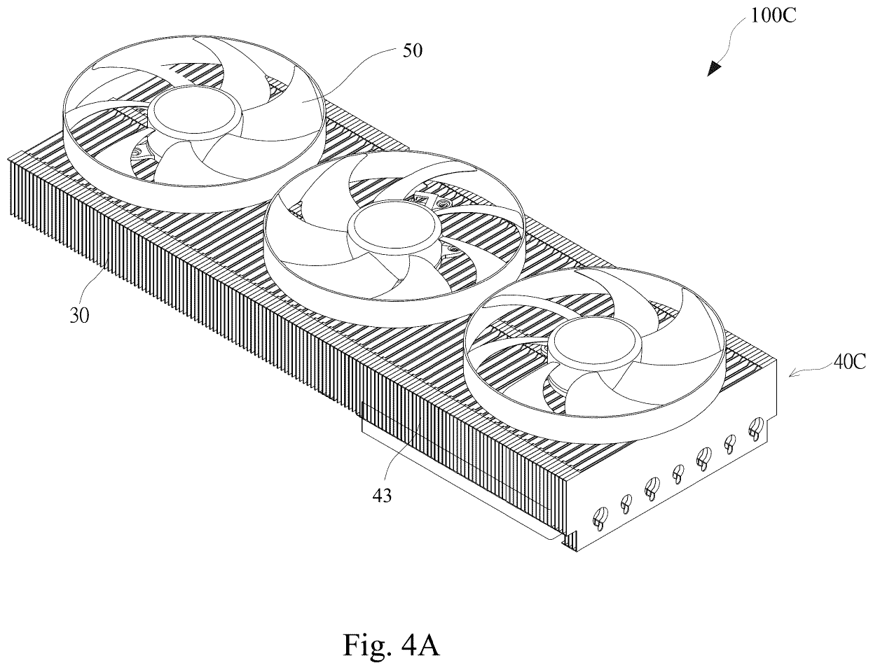

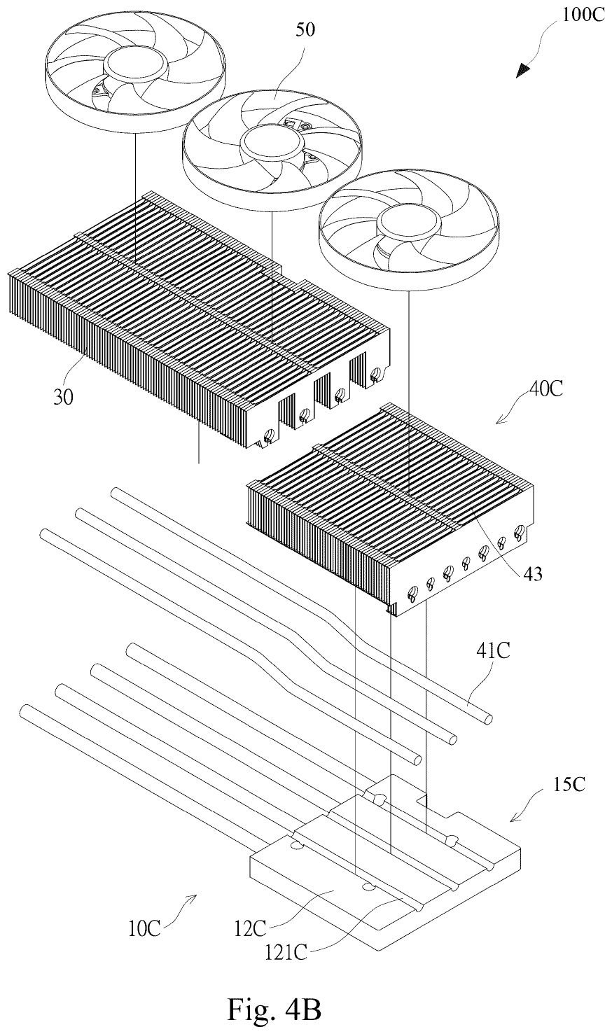

FIGS. 4A, and 4B illustrate yet another alternative cooling system assembly 100C, in accordance with various embodiments of the present disclosure. The yet another alternative cooling system assembly 100C may be similar in some respects to the cooling system assembly 100 of FIGS. 1A, 1B, 1C, and 1D, and therefore may be best understood with reference thereto where like numerals designate like components not described again in detail. The water block unit 40C of the yet another alternative cooling system assembly 100C includes a second plurality of heat pipes 41C and a second fin stack 43, and the heat pipe heatsink 15C further includes a plurality of second heat pipe grooves 121C. Each second plurality of heat pipes 41C is thermally coupled in each plurality of second heat pipe grooves 121C. The second fin stack 43 is thermally coupled to the heat pipe heatsink 15C. The second plurality of heat pipes 41C is between the second thermal transfer surface 12C and the second fin stack 43. The second plurality of heat pipes 41C is configured to enable the heat to be further transported from the second thermal transfer surface 12C to the second cooling liquid and away from the heat pipe heatsink 15C. The second plurality of heat pipes 41C can be thermally coupled using a welding or other joining technique.

In some embodiments, the yet another alternative cooling system assembly 100C further includes a plurality of fan devices 50. In some embodiments, each plurality of fan devices 50 is disposed on the fin stack 30 or on the fin stack 30 and the second fin stack 43. Each plurality of fan devices 50 is configured to enable air to be forced across the fin stack 30 and the second fin stack 43.

Thermal conductivity of the heatsink units 10/10A/10C of the embodiments is increased. The fin stack 30 is disposed on one side of the water block unit 40/40A/40B/40C. Thus, the heat is transported from the heat sink unit 10/10A/10C to the fin stack 30 on one side, and the water block unit 40/40A/40B/40C is able to be disposed directly on top of the second thermal transfer surface 12/12A/12C, so that the heat can also be transported from the heat sink unit 10/10A/10C to the water block unit 40/40A/40B/40C. The third thermal transfer surface 42 of the heat dissipation cover 45 can further transport heat from the heat pipe heatsink 15 to the second fin stack 43. Moreover, the heat dissipation cover 45 can be a vapor chamber for increased heat dissipation efficiency. The liquid cooling pumping unit 44B can be coupled on the plurality of heat transfer surface features 43A, to increase a pressure and a flow of the second cooling liquid through the plurality of heat transfer surface features 43A. Thus, greater thermal conductivity of the heat sink units 10/10A/10C is provided, increasing the effectiveness and efficiency of the cooling system assemblies 100/100A/100B/100C.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

1. A cooling system assembly, comprising:
a heatsink unit configured to enable a first cooling liquid to undergo a phase-change, the heatsink unit including a heat pipe heatsink comprising a first thermal transfer surface and a second thermal transfer surface, the second thermal transfer surface opposite the first thermal transfer surface, the first thermal transfer surface configured to enable a heat to be transported from at least one packaged integrated circuit to the heat pipe heatsink; and
a water block unit configured to enable a second cooling liquid to flow through the water block unit, the water block unit thermally coupled to the second thermal transfer surface, the second thermal transfer surface configured to enable the heat to be further transported from the heat pipe heatsink to the water block unit.

2. The cooling system assembly of claim 1, wherein the heatsink unit further comprises a fin stack and a plurality of heat pipes, each plurality of heat pipes thermally coupled to the heat pipe heatsink on a heatsink end and each plurality of heat pipes thermally coupled to the fin stack on a fin end opposite the heatsink end.

3. The cooling system assembly of claim 2, wherein the fin stack is disposed on one side of the heat pipe heatsink, the plurality of heat pipes comprises seven plurality of heat pipes, and four of the seven plurality of heat pipes are parallel aligned at a bottom distance of the fin stack from a bottom of the fin stack, and three of the seven plurality of heat pipes are parallel aligned at an upper distance of the fin stack from the bottom of the fin stack, the upper distance larger than the bottom distance.

4. The cooling system assembly of claim 2, wherein the heat pipe heatsink further comprises a heatsink length, and the fin stack comprises a fin length and a fin width, the fin length greater than the fin width, the fin length greater than the heatsink length.

5. The cooling system assembly of claim 2, wherein the water block unit comprises a heat exchanger tubing and a heat dissipation cover, the heat exchanger tubing thermally coupled between the second thermal transfer surface and the heat dissipation cover, the heat exchanger tubing including an inlet tube connector and an outlet tube connector, the inlet tube connector configured to enable the second cooling liquid to be transported into the water block unit, the outlet tube connector configured to enable the second cooling liquid to be transported out of the water block unit, the heat exchanger tubing configured to enable the heat to be further transported from the second thermal transfer surface to the second cooling liquid and then out of the water block unit.

6. The cooling system assembly of claim 5, wherein the second thermal transfer surface comprises a second surface groove, the heat dissipation cover comprises a plate surface groove, and the heat exchanger tubing further includes a second surface side and a heat dissipation cover side, the second surface side opposite the heat dissipation cover side, the second surface side abuts the second surface groove, the heat dissipation cover side abuts the plate surface groove, and the inlet tube connector and the outlet tube connector disposed on a same side of the water block unit.

7. The cooling system assembly of claim 5, wherein the water block unit further comprises a second fin stack, and the heat dissipation cover comprises a third thermal transfer surface, the second fin stack thermally coupled to the third thermal transfer surface, the second fin stack configured to enable the heat to be further transported from the water block unit to the second fin stack.

8. The cooling system assembly of claim 5, wherein the heat dissipation cover is a vapor chamber, the vapor chamber configured to enable the phase-change of a third cooling liquid in the vapor chamber.

9. The cooling system assembly of claim 2, wherein the water block unit comprises a base plate cavity, and a plurality of heat transfer surface features, the plurality of heat transfer surface features disposed in the base plate cavity, the base plate cavity thermally coupled centrally on the second thermal transfer surface, the plurality of heat transfer surface features configured to enable the heat to be further transported from the heat pipe heatsink to the plurality of heat transfer surface features, and then to the second cooling liquid, and then out of the water block unit.

10. The cooling system assembly of claim 9, wherein the water block unit further comprises a cover plate, a plate inlet, and a plate outlet, the cover plate coupled on the water block unit, the plurality of heat transfer surface features between the second thermal transfer surface and the cover plate, the plate inlet and the plate outlet respectively fluidly coupled through the cover plate to the base plate cavity, the plate inlet configured to enable the second cooling liquid to be transported into the water block unit, the plate outlet configured to enable the second cooling liquid to be transported out of the water block unit.

11. The cooling system assembly of claim 9, wherein the water block unit further comprises a liquid cooling pumping unit, the liquid cooling pumping unit including an inlet connector and an outlet connector, the liquid cooling pumping unit coupled on the water block unit, the plurality of heat transfer surface features between the second thermal transfer surface and the liquid cooling pumping unit, the liquid cooling pumping unit fluidly communicated with the base plate cavity, the liquid cooling pumping unit configured to enable a pressure and a flow of the second cooling liquid to be increased and transported through the plurality of heat transfer surface features and out of the water block unit.

12. The cooling system assembly of claim 2, wherein the water block unit comprises a second plurality of heat pipes and a second fin stack, and the heat pipe heatsink further comprises a plurality of second heat pipe grooves, each second plurality of heat pipes thermally coupled in each plurality of second heat pipe grooves, the second fin stack thermally coupled to the heat pipe heatsink, the second plurality of heat pipes between the second thermal transfer surface and the second fin stack, the second plurality of heat pipes configured to enable the heat to be further transported from the second thermal transfer surface to the second cooling liquid and away from the heat pipe heatsink.

13. The cooling system assembly of claim 7, further comprising a plurality of fan devices, each plurality of fan devices disposed on the fin stack or on the fin stack and the second fin stack, each plurality of fan devices configured to enable air to be forced across the fin stack and the second fin stack.
